(19) United States
(12) Patent Application Publication
(10) Pub. No.: US 2025/0330167 A1
(43) Pub. Date: Oct. 23, 2025

(54) HIGH LINEARITY AND HIGH SWITCHING SPEED RADIO FREQUENCY SWITCH WITH DIRECT CURRENT CONTROL

(71) Applicant: LINTRINSIC SEMICONDUCTORS INC., Cambridge, MA (US)

(72) Inventors: Cameron HILL, Somerville, MA (US); Giuseppe MICHETTI, Boston, MA (US)

(73) Assignee: LINTRINSIC SEMICONDUCTORS INC., Cambridge, MA (US)

(21) Appl. No.: 19/185,045

(22) Filed: Apr. 21, 2025

Related U.S. Application Data
(60) Provisional application No. 63/636,590, filed on Apr. 19, 2024.

(51) Int. Cl. H03K 17/041

(52) U.S. Cl. CPC H03K 17/04106

(57) ABSTRACT

A method and apparatus are disclosed providing fast linear switching from DC to several GHz. The switch has fast switching times, remains linear over a wide frequency range, and can be used with a DC drive signal. A control signal port is connected to a high voltage driver, a signal input port, and an output port. A first resistor provides a signal path and a first capacitor is connected in series with the gate of the FET and a second resistor is connected in series between the gate of the FET and the first capacitor.

### CROSS-REFERENCE TO RELATED APPLICATIONS—CLAIM OF PRIORITY

The present application claims priority to U.S. Provisional Application No. 63/636,590, filed Apr. 19, 2024, entitled “High Linearity and High Switching Speed Radio Frequency Switch with Direct Current Control,” which is herein incorporated by reference in its entirety.

### BACKGROUND

### (1) Technical Field

The disclosed method and apparatus relate generally to high-speed switches. In particular, the disclosed method and apparatus relate to high-speed radio frequency switches capable of being controlled with a direct current control signal.

### (2) Background

An inherent trade-off exists between switching speed and linearity in RF (Radio Frequency) switches. Single-pole double-throw (SPDT) switches are widely used in commercial transmit and receive modules in RF applications, in part because they allow scaling to other transmit/receive configurations. Other configurations may be single-pole single-throw, single-pole quadruple-throw and single-pole octuple-throw. Each branch of the switch comprises a series-shunt configuration for improved isolation and may also comprises inductors on the inputs and outputs, creating a T-type matching network for broadband performance.

FIG. 1 is an illustration of the basic SPDT architecture of the RF switches discussed in further detail below. The switch architecture 100 incudes input pins P1 102, P2 104, and P3 106. The pins 102, 104, and 106 are connected to inductors 108, 110, and 112. In turn, inductors 108, 110, and 112 are connected to a junction connecting the two throw switches of each SPDT. Switch 114 is connected to the output of switch 116 and to inductor 110. Switch 116 is connected to the output of switch 114 and inductor 110. Switch 118 is connected to the output of switch 120 and to inductor 112. Switch 118 is also connected to ground 122 and switch 120 is connected to ground 124.

One of the significant factors in the trade-off between switching and linearity is the large resistances connected to the gates of the FET (Field Effect Transistor) switches. These resistances are required to maintain the desired state of the switch through the entire RF phase however, they also slow down the speed of the switch. In the past, attempts have been made to increase the switching speed while maintaining the linearity of the switch. In some cases, this has been attempted by modulating the gate resistance with a switch (i.e., adjusting the amount of resistance that is imposed by dynamically controlling the resistance of a FET through which the current flows rather than having a fixed resistance). However, these approaches expose the switches to high voltages at the switching intervals, making them unsuitable for hot switching designs (i.e., designs in which a signal flows through the switch during switching). Hot switching designs may be needed for RF applications.

Other approaches to mitigate the trade-offs use a technique that capacitively divides the drive voltage between the internal FET gate capacitor and a carefully designed external capacitor. The external capacitor provides a high impedance on the gate to allow the RF signal to remain linear, without degrading the RC (resistive/capacitive) rise-time of the switch, which would result if a resistor were used to increase the impedance.

FIG. 2 is an illustration of a schematic of a circuit 200 in which a capacitive network includes an extrinsic gate capacitor 202 (a capacitor that is external to the FET 204) to provide a high impedance at the gate 206 of the FET 204 from the perspective of an RF signal 208 that passes through the FET 204 between the drain 210 to source 212. Adding external capacitance enhances the breakdown voltage of the FET without the need for a custom fabrication process to set the breakdown voltage at the desired level. The transfer function of the control voltage (V_{control}) to the gate voltage (V_{g}) 213 is:

$${V}_{g} = \frac{j ω {C}_{g e x} {R}_{b i a s}}{1 + j ω {R}_{b i a s} ( {C}_{g e x} + {C}_{g i n} )} {V}_{control} \qquad EQ . 1$$

It can be seen from EQ. 1 that the gate voltage (V_{g}) 213 increases with higher frequency (i.e., relatively high values of jω). Furthermore, at DC (with jω=0), the value of the control voltage (V_{control}) drops to zero. Even at low frequencies that are not pure DC (the impedance through C_{gex} being theoretically infinite at DC), Vg will be a relatively smaller and smaller fraction of V_{control} as the frequency drops. Accordingly, the circuit 200 is not suitable for use with relatively low frequency control signals.

The gate capacitor approach has previously been implemented in a high linearity quad-FET mixer manufactured on a silicon-on-insulator substrate. However, these implementations typically assume that the driving signal of the switch has a 50% duty cycle. In such cases, the DC component of the controlling signal is zero. However, such cases in which there is a zero DC component, the switch and switch driver are incapable of holding a constant state. Accordingly, such switches are inappropriate for use as SPDT (signal pole, double throw) switches, because if the switch is to be used with a control signal having a DC component, the DC component of the control signal will disrupt the bias, due to an accumulating charge across the capacitances that shifts the switches bias over time.

Another problem with the gate capacitor approach is that it makes it necessary to have a high-voltage drive signal 214 available to operate the FET 204, thus making it more difficult to design a driving amplifier 216 to provide the required drive signal 214. One way to attain a high-voltage driver 216 capable of generating the desired high-voltage drive signal 214 is to use a FET stacking technique.

FIG. 3 is an illustration of a circuit 300 implementing FET stacking. Such FET stacking results in a driver 216 that can supply the necessary gate voltage (V_{g}) 213 to provide switching times in the order of 10s of picoseconds. Theoretically, switching times for such implementations are only limited by the process technology and the driver architecture. However, the circuit 200, fails to provide a “true DC response” because a coupling and biasing capacitor (C_{bias}) 302 is required to drive the top PMOS (Positive Metal Oxide Semiconductor) FET (Q1, p) 304a to maintain the correct DC bias at the gate of the FET (Q1, p) 304a. Clearly, the contribution from the control voltage (V_{control}) drops to zero at the gate of FET (Q1, p) 304a as the frequency of the control voltage (V_{control}) approaches DC and the voltage on the gate of the top FET (Q1, p) 304a will drift back towards the default bias (typically VDD−0.5V_{proc} with V_{proc} being the process voltage of the semiconductor node used in the design).

Throughout this discussion, elements of the figures referenced with a reference designation that comprises a numeric component followed by an alphabetic component, such as the reference designation “304a” are essentially identical to other elements of the figures represented by a reference designation having the same numeric component, but a different alphabetic component (e.g., “304b”). Furthermore, all such elements referenced by reference designations with the same numeric component may be referenced collectively by a reference designation comprising only the numeric component (e.g., “304”).

FIG. 4 is an illustration of a driver circuit 400 using a latching mechanism 402. The driver circuit 400 partially addresses the problem noted above that occurs at low frequency, with regard to the driver circuit 300, by adding the two-stage inverter latch 402 to replace the top resistor 308a and bottom bias resistor 308f (see FIG. 3). It should be noted that the driver 400 has four P-type FETs 404 and four N-type FETs 406, whereas the driver 300 has only three such P-type FETs 304 and N-type FETS 306. The driver circuit 400 removes the effect of DC biases from data signals when transmitting at high frequency. However, it does not solve a problem that exists for strictly DC control. That is, for example in the driver 400 of FIG. 4, there is still a resistive path that causes biasing drift at very low frequency operation and leads to a failure of the latching mechanism. The resistive path is from the output (Vₒᵤₜ) 405 through the resistor 410 and bias resistors 408 to the gates of each of the FETs 404, 406 in the stack.

Therefore, it would be desirable to be able to deal with the DC offset limitations noted above. The presently disclosed method and apparatus deals with the DC offset limitations in a manner that is desirable.

### SUMMARY

Various embodiments of a method and apparatus are disclosed for providing a switch that has very fast switching times, remains linear over a wide frequency range, and can be used with a DC (Direct Current) drive signal. In particular, the presently disclosed method and apparatus provides a switch comprising a control signal port connected to a high voltage driver as well as a signal input port and an output port. The switch also includes a filed effect transistor (FET) with the source of the FET connected to the signal output port and the drain connected to the signal input port. A first resistor provides a signal path between the drain and gate of the FET. A first capacitor is connected in series with the gate of the FET and a second resistor is connected in series between the gate of the FET and the first capacitor. A third resistor is connected in parallel with the first capacitor and the second resistor. The switch uses a voltage dividing network in parallel with a capacitor on the gate of the FETs (Field Effect Transistors) to allow a DC signal to pass to the gate without causing oxide breakdown, while still maintaining a fast-switching speed.

In addition, the presently disclosed method and apparatus uses a latching network within stacked drivers to ensure that the state of the driver is maintained, even when the control line is operating at DC.

Still further, the presently disclosed method provides a method of manufacturing switch assemblies incorporating a resistive dividing network and stacked field effect transistors (FETs).

### BRIEF DESCRIPTION OF THE DRAWINGS

The disclosed method and apparatus, in accordance with one or more various embodiments, is described with reference to the following figures. The drawings are provided for purposes of illustration only and merely depict examples of some embodiments of the disclosed method and apparatus. These drawings are provided to facilitate the reader's understanding of the disclosed method and apparatus. They should not be considered to limit the breadth, scope, or applicability of the claimed invention. It should be noted that for clarity and ease of illustration these drawings are not necessarily made to scale.

FIG. 1 is an illustration of the basic SPDT architecture.

FIG. 2 is an illustration of a schematic of a circuit in which a capacitive network includes an extrinsic gate capacitor to provide a high impedance at the gate of a switch FET.

FIG. 3 is an illustration of a circuit implementing FET stacking.

FIG. 4 is an illustration of a driver circuit using a latching mechanism.

FIG. 5 is an illustration of dominant parasitics in a silicon-on-insulator field effect transistor (SOI FET) in accordance with some embodiments of the disclosed method and apparatus.

FIG. 6 is an illustration of a basic FET cell layout in accordance with some embodiments of the disclosed method and apparatus.

FIG. 7 is an illustration of FET cells in a tiled formation used to manufacture a 20-stack switch in accordance with some embodiments of the disclosed method and apparatus.

FIG. 8A is an illustration of a FET architecture and the main capacitances in accordance with some embodiments of the disclosed method and apparatus.

FIG. 8B is a block diagram of a FET architecture and the main capacitances in accordance with some embodiments of the disclosed method and apparatus.

FIG. 9 is a block diagram of the compensation capacitance used to maintain voltage division in accordance with some embodiments of the disclosed method and apparatus.

FIG. 10 is a schematic diagram illustrating parasitics in RF switch packaging in accordance with some embodiments of the disclosed method and apparatus.

FIG. 11A illustrates a large SOI RFIC die without down-bonds as a packaging solution for a stacked FET RF switch in accordance with some embodiments of the disclosed method and apparatus.

FIG. 11B illustrates a large SOI RFIC die with down-bonds as a packaging solution for a stacked FET RF switch in accordance with some embodiments of the disclosed method and apparatus.

FIG. 11C illustrates the effect of a large SOI RFIC die with and without down-bonds on bond inductance in accordance with some embodiments of the disclosed method and apparatus.

FIG. 11D illustrates the effect of a large SOI RFIC die with and without down-bonds on bond resistance in accordance with some embodiments of the disclosed method and apparatus.

FIG. 11E illustrates the effect of a large SOI RFIC die with and without down-bonds on bond inductance and resistance as well as the effect on the effective wave impedance in accordance with some embodiments of the disclosed method and apparatus.

FIG. 12A illustrates an excitation current distribution for a large SOI RFIC die with an RF signal exciting the antenna port, in accordance with some embodiments of the disclosed method and apparatus.

FIG. 12B illustrates the coupling-limited boundaries of a large SOI RFIC with and without down-bonds in accordance with some embodiments of the disclosed method and apparatus.

FIG. 12C illustrates the packaging ground inductance of a large SOI RFIC die with and without down-bonds in accordance with some embodiments of the disclosed method and apparatus.

FIGS. 13A and 13B illustrate post layout insertion loss and isolation for a 50 W SPDT switch operating on frequencies up to X-band in accordance with some embodiments of the disclosed method and apparatus.

FIGS. 14A and 14B illustrate post layout insertion loss and isolation for a 250 W SPDT switch operating on frequencies in the L and S-bands in accordance with some embodiments of the disclosed method and apparatus.

FIG. 15 is a schematic diagram of the DC circuit used for thermal modeling in accordance with some embodiments of the disclosed method and apparatus.

FIGS. 16A and 16B are graphs showing an estimated range of temperature increase based on input power for a 0.3 dB loss SPDT FET switch in accordance with some embodiments of the disclosed method and apparatus.

FIG. 17 is a schematic diagram of a fast-switching SOI FET cell in accordance with some embodiments of the disclosed method and apparatus.

FIG. 18 is a schematic diagram of a fast-switching SOI FET cell in accordance with further embodiments of the disclosed method and apparatus.

FIG. 19 is a schematic diagram of a stacked fast-switching SOI FET assembly in accordance with further embodiments of the disclosed method and apparatus.

FIG. 20 is a flowchart illustrating the method by which a semiconductor switch assembly driver stack is designed and manufactured in accordance with some disclosed embodiments.

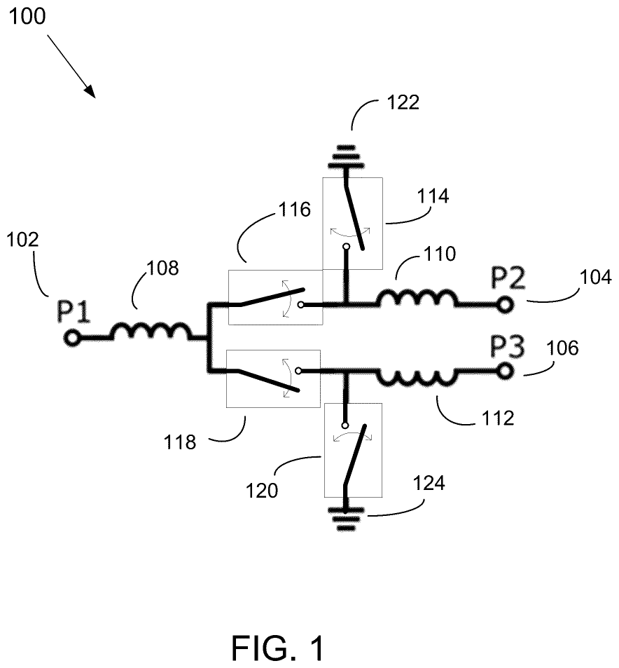

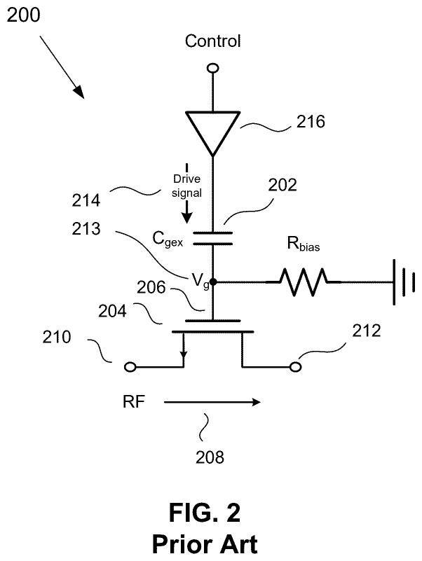

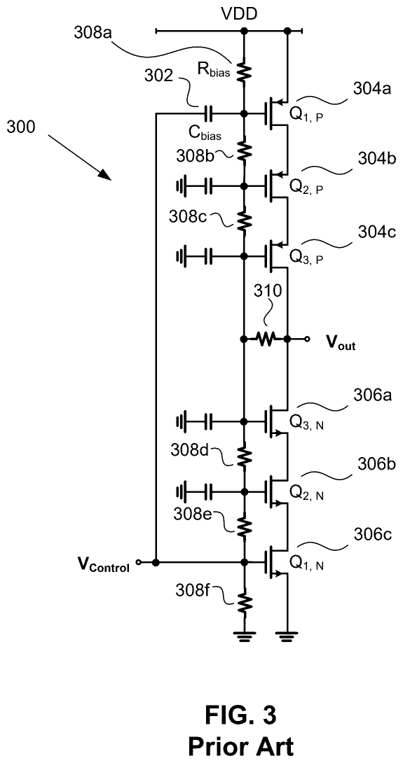

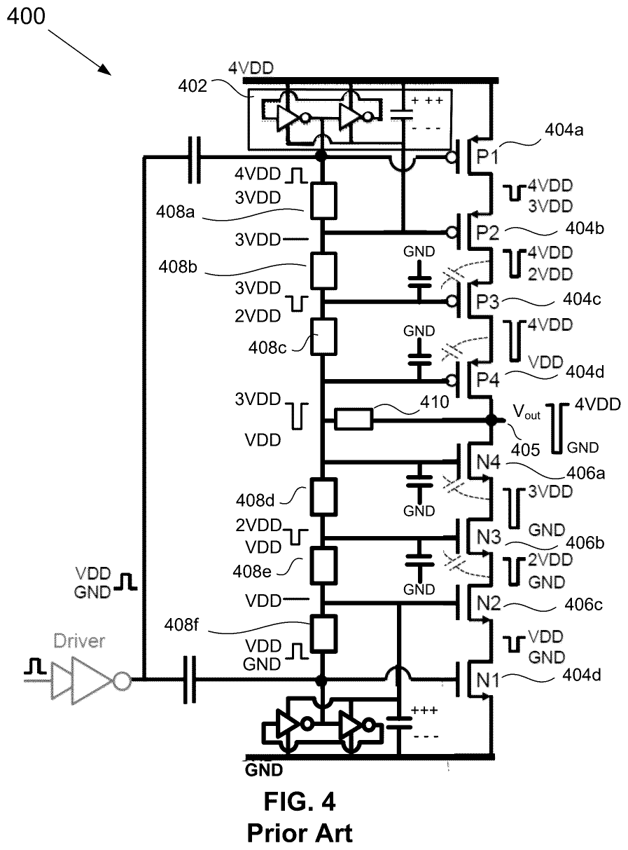

The figures are not intended to be exhaustive or to limit the claimed invention to the precise form disclosed. It should be understood that the disclosed method and apparatus can be practiced with modification and alteration, and that the invention should be limited only by the claims and the equivalents thereof.

### DETAILED DESCRIPTION

The disclosed method and apparatus provides a high-speed switch that is highly linear and that can be used with a DC (direct current) control signal. Being operational at DC makes it possible to use the switch as an SPDT (signal pole, double throw) switch (i.e., to hold an ON or OFF state for relatively long periods of time).

### Switch Architecture

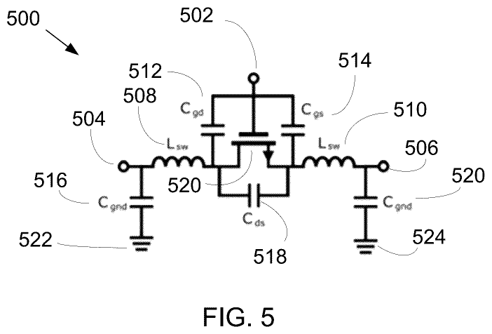

FIG. 5 is an illustration of dominant parasitics in a silicon-on-insulator field effect transistor (SOI FET) 500. The SOI FET 500 comprises a transistor where the semiconductor channel is built on top of a layer of insulating material, a buried oxide, on top of a silicon substrate. SOI FETs provide improved performance and reduced parasitic effects compared to traditional silicon transistors. The buried oxide layer isolates the active silicon channel from the rest of the substrate, which minimizes interference and improves device characteristics.

The SOI FET 500 shown in FIG. 5 was used as part of a test layout to simulate and measure parasitic components. During testing, parasitic components of the individual SOI FET cells were extracted from realistic layouts and fed back to non-linear models to produce improved large signal simulation accuracy.

The SOI FET 500 has pins 502, 504, and 506. Pin 504 is connected to a first inductor L_{switch} 508, while pin 506 is connected to a second inductor L_{switch} 510. Pin 502 is connected to FET 520, which is connected to L_{switch} 508 on the input and L_{switch} 510 on the output. L_{switch} 508 has a branch connection to capacitor C_{gate} drain 512 and capacitor C_{gate} source 514. Capacitor C_{gate} source 514 is also connected to L_{switch} 510. In addition, inductor L_{switch} 508 is connected to capacitor C_{drain} source 518. Pin 504 is also connected to capacitor C_{ground} 516, while pin 506 is also connected to capacitor C_{ground} 520. Capacitor C_{ground} 516 and Capacitor C_{ground} 520 are respectively connected to grounds 522 and 524.

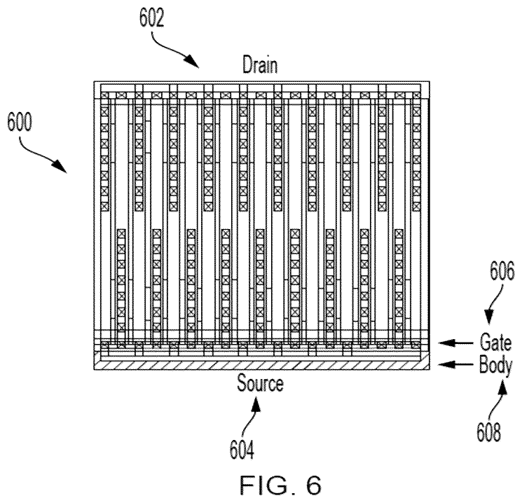

FIG. 6 is an illustration of a basic FET cell layout in accordance with some embodiments of the disclosed method and apparatus. The basic FET cell layout 600 includes drain 602 and source 604. The gate 606 is shown as part of the body 608. The starting point of the design work began by extracting the parasitic components of the individual FET cells, each of which is modeled by the basic FET cell 600 of FIG. 6. As an illustration, FIG. 6 depicts a FET cell 600 with 2.5 ohms of series resistance designed for use in a high-performance RF applications requiring multi-band RF switching, optimized performance, in a small die area.

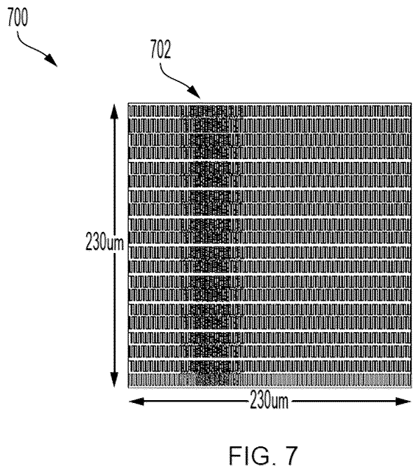

FIG. 7 is an illustration of FET cells in a tiled formation used to manufacture a 20-stack switch. The switch 700 includes FET cells 702 tiled to form the switch. The switch 700 is depicted as being 230 μm by 230 μm, however, this is for illustrative purposes only and other dimensions may be selected, depending on the application, and are encompassed by this disclosure. The cells described in FIG. 7 may be tiled indefinitely to create any desired size of stack, while still maintaining a square aspect ratio. The square aspect ratio depicted in FIG. 7 minimizes ground parasitics.

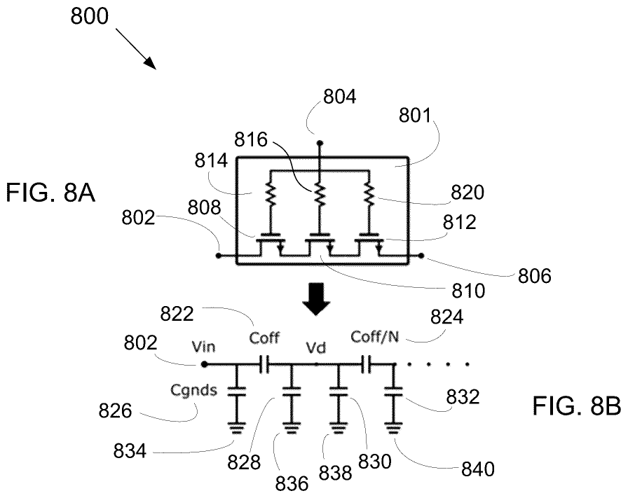

FIG. 8A illustrates a stacked FET architecture including the main capacitances, in accordance with some embodiments of the disclosed method and apparatus. The RF switch architecture 800 includes a switch stack 801 and input pins 802 and 804 and output 806. Input pin 802 is connected to FETs 808, 810 and 812 through the switch stack 801. FET 808 is also connected to FET 810 and FET 810 is also connected to FET 812. FET 808 is connected to resistor 814. FET 810 is connected to resistor 816 and FET 812 is connected to resistor 820. Resistors 814, 816, and 820 are connected to one another through the switch stack 801, which in turn is connected to pin 804.

When RF switches are stacked in series to increase the power handling of the RF switch, as illustrated in FIG. 8A the parasitic capacitance to ground effects the voltage division across each FET device, in accordance with equation 1 below:

$${V}_{d} = \frac{{C}_{off}}{{C}_{off} + ( \frac{{C}_{off}}{N} + {C}_{gnd} )} {V}_{i n} \qquad EQ . 2$$

Where N is the number of stacked devices. The excess voltage produces an unequal voltage drop across the stacked devices when the switches are in the OFF state. This causes the RF switch to compress before the ideal limit. The ideal limit is N times the process rated breakdown voltage. This compression effect can be compensated by adding compensation capacitance, known as C_{compensationN} across each device.

FIG. 8B is a block diagram of a FET architecture and the main capacitances in accordance with some embodiments of the disclosed method and apparatus. The RF switch architecture 800 block diagram provides an input voltage Vᵢₙₚᵤₜ on pin 802. Capacitor 822 represents an off state and is identified as C_{off}, and capacitor 824 represents a further off state per stacked device, N, and is identified as C_{off/N}. Pin 802 is also connected to a grounding capacitor 826, identified as C_{ground}. Capacitors 828, 830, and 832 are also grounding capacitors. Each grounding capacitor 826, 828, 830, and 832 is connected to a respective ground 834, 836, 838, and 840. C_{off} 822 is also connected to C_{ground} 826 and C_{ground} 828. C_{off} 822 is connected in series with C_{off/N} 824, C_{ground} 826 and C_{ground} 828. C_{off/N} 824 is connected to C_{ground} 830 and C_{ground} 832.

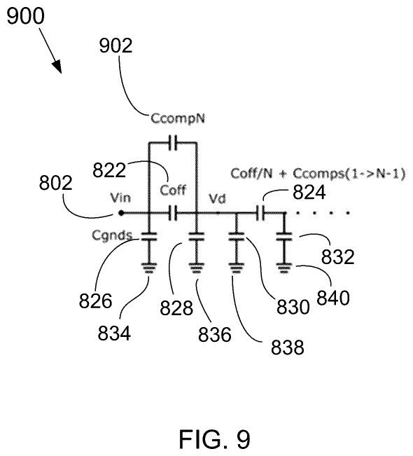

FIG. 9 is a block diagram of the compensation capacitance used to maintain voltage division in accordance with some embodiments of the disclosed method and apparatus. The compensation capacitance circuit 900 has the voltage input pin 802 that provides voltage to the capacitor C_{compensationN} 902. After C_{compensationN} 902, drain voltage V_{drain} is provided to the offset capacitor C_{off/N} 822, which is added to the compensation capacitor C_{compensation(1->N-1)} 902. The input voltage is also provided to grounding capacitors in parallel C_{ground} 826, 828, 830, and 832. Each of the grounding capacitors 826, 828, 830, and 832 are connected respectively to grounds 834, 836, 838, and 840.

The compensation capacitance circuit 900 provides the increased compensation capacitance needed across the circuit and is determined by the following equation:

$${C}_{c omp , N} = {C}_{g n d} {Σ}_{n = 1}^{N - 1} n \approx {C}_{g n d} ( \frac{N}{2} + \frac{{N}^{2}}{2} ) \qquad EQ . 3$$

This additional compensation compensates for the ground parasitic capacitance results in a significant degradation of the figure of merit of the entire switch stack, 801. This parasitic effect will dominate the input capacitance Cᵢₙₚᵤₜ an effect that only increases as the number, N, of FETs in the switch stack 801 increases. This relationship shows that the τ=RₒₙCᵢₙ product for a stack of N FETs is shown in the following equation:

$$τ = {R}_{o n} {C}_{o f f} ( 1 + \frac{{C}_{g n d}}{2 {C}_{o f f}} {N}^{2} ) \qquad EQ . 4$$

This parasitic effect eventually dominates the input capacitance, Cᵢₙₚᵤₜ of the switch and determines the SPDT bandwidth.

The ground capacitance, C_{ground} has two components, the area capacitance, for a standard parallel plate, and the fringing capacitance. Each of these capacitances scales with area and perimeter and also scales with the number of stacks because there is no internal fringing capacitance at the internal ground capacitance, C_{ground} nodes. As a result, to correctly estimate the value of the compensating capacitance, C_{compensation}, a fitting function is needed at each FET in the switch stack 801. This fitting function is based on the size of the individual FET and the size of the total switch stack 801.

Determining the total value of the grounding capacitance, C_{ground}, used switch cells that ranged in size from 1 to 20 FETs. These switch cells were then extracted to determine the total value of the ground capacitance, C_{ground}. One example uses 200 nm switches, known as 7SW devices, to determine the value of both the area capacitance, Cₐᵣₑₐ and perimeter capacitance Cₚₑᵣᵢₘₑₜₑᵣ, using the equations below:

$${C}_{g nd , total} = {C}_{p e r imeter} N \sqrt{\frac{{R}_{b a s e}}{R}} + \frac{{C}_{a r e a} {N}^{2} {R}_{b a s e}}{R} \qquad EQ . 5$$

$${C}_{gnd / FET} = {C}_{p erimeter} \sqrt{\frac{{R}_{b a s e}}{R}} + \frac{{C}_{a r e a} N {R}_{b a s e}}{R} \qquad EQ . 6$$

$$Where {C}_{p e r i m e 𝔠 e r} = 3.32 f F , {C}_{area} = 0.06 fF , and {R}_{b a s e} = 2.5 Ω$$

These equations and the extracted constants may be used with many silicon processes with little variation across processes. This is because the equations consider the Rₒₙ density of the switches and consider scaling of the area as the switch cells grow to reduce Rₒₙ. Testing has verified the equations when utilized with several different unit cells and stacked switch points. As the stack size increases, the ground capacitance, C_{ground/FET} increases linearly the area of the stacked FETs, however, the perimeter capacitance per FET remains the same. Offset capacitance, C_{off/FET}, also increases linearly with the stack height, resulting in the total ratio of offset capacitance to ground capacitance, C_{off} to C_{ground} dropping as the height of the stack increases. In addition, the power handling capability of the switch increases. These features favor adoption of silicon on insulator (SOI) stacked FETs for applications requiring high-power and in broad band applications. The RF switch design thus benefits from the improved RₒₙC_{off} of SOI devices, while maintaining excellent parasitic ground capacitance, C_{ground} per stage. Designs can provide for large FET stacks to ensure greater power handling and thermal efficiency.

### Packaging

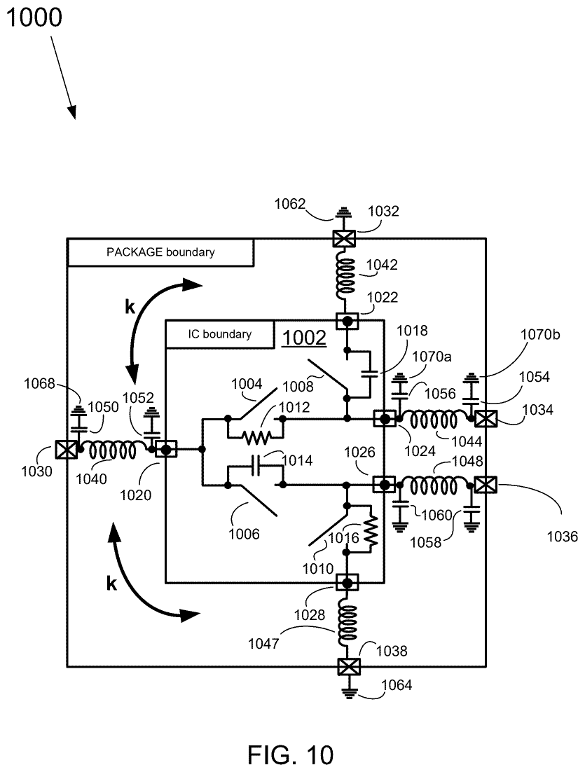

FIG. 10 is a schematic diagram illustrating parasitics in RF switch packaging in accordance with some embodiments of the disclosed method and apparatus. Packaging the stacked-FET RF switches is a critical effort to enable low-cost and high-volume production. Considerations to be considered include RF loss and isolation, thermal sinking, and unit cost. These considerations may affect the selection of packaging solutions.

Multiple packaging solutions may be considered, including flip-chip bumping and wire bonding on a quad-lead frame. Flip-chip bumping using wafer-scale chip level packaging is one option that offers minimal RF inductance while providing very good RF isolation. Unfortunately, heat dissipating may be problematic with flip-chip bumping as the thermal path is limited by the bumps, which limit heat transfer. Mitigating the heat transfer issues in flip-chip bumping may require custom or tailored underfills and specialized bumps, designed for the specific design. This may increase both production costs and time for the end user. In contrast, wire bonding on a quad-lead frame is significantly less expensive and provides much faster design integration, because standardized quad-lead frame molds may be used.

Thermal conductivity may be maximized with thermally conductive die-attach pastes and wafer thinning, the challenge of addressing the increased parasitic interconnects remains. FIG. 10 illustrates the parasitics interconnects on a RF switch with the stacked FET configuration discussed above. The packaged RF switch 1000 includes an RF switch die 1002. The RF switch die 1002 includes RF switches 1004, 1006, 1008, and 1010, where the RF switches are in a stacked FET configuration. RF switch 1004 is connected to resistor 1012, RF switch 1006 is connected to a capacitor 1014, RF switch 1008 is connected to a capacitor 1018, and RF switch 1010 is connected to resistor 1016.

The RF switch assembly die 1002 has die interconnects 1020, 1022, 1024, 1026, and 1028 that connect respectively to RF switches 1004, 1006, 1008, and 1010. The die interconnects 1020, 1022, 1024, 1026, 1028 are connected to package interconnects 1030, 1032, 1034, 1036, and 1038, respectively. Parasitic inductances and capacitances are present between the die interconnects and the package interconnects. A die interconnect may have parasitic inductance only, such as die interconnect 1022 with parasitic inductance 1042. Die interconnect 1028 has an associated parasitic inductance 1047. Other die interconnects may have both parasitic inductance and parasitic capacitance. For example, die interconnect 1020 has a parasitic inductance 1040 and parasitic capacitances 1050 and 1052. Similarly, die interconnect 1024 has parasitic inductance 1044 and parasitic capacitances 1054 and 1056. Die interconnect 1026 has parasitic inductance 1048 and parasitic capacitances 1058 and 1060. Package RF switch 1000 has grounds 1062 and 1064, which are connected to package interconnects 1032 and 1038, respectively.

The parasitic inductances and capacitances shown in FIG. 10 may be addressed during the design phase. In the schematic of FIG. 10, the typical shunt capacitive load of SPDT RF switch may be matched to a 50-ohm environment using the parasitic series-L reactance of the RF wire bonds of the quad-lead frame, thus providing improved RF performance. Simulations show that for a 10 GHz design, inductances down to 500 pH may be synthesized with double bonds, with Q greater than 100. This design solution eliminates the need to use thick on-chip copper traces for the matching inductors, offering additional cost savings, mitigating RF loss, while at the same time improving thermal management by leveraging high-Q inductors.

Ground inductance and mutual coupling between RF pins may impose limits on RF isolation that should be evaluated during the design process.

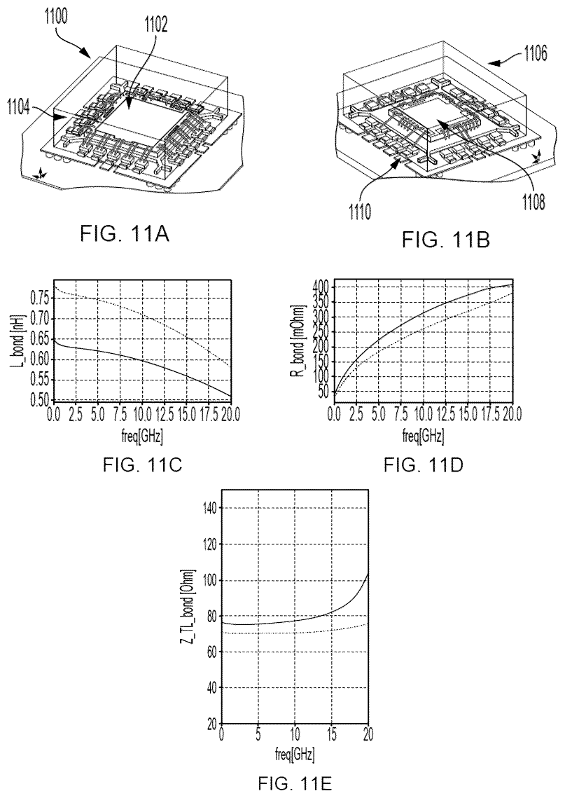

FIG. 11A illustrates a large SOI RFIC die without down-bonds as a packaging solution for a stacked FET RF switch in accordance with some embodiments of the disclosed method and apparatus. Proof-of-concept testing of the embodiments described herein included creating a three-dimensional electromagnetic model of the proposed structure. This model was analyzed to produce the packaging options depicted in FIGS. 11A and 11B. FIG. 11A illustrates packaged RFIC die 1100 that incorporates a 2.5 mm×2.5 mm SOI RFIC die 1102 that covers the entire die-attach paddle. The SOI RFIC die 1102 has bonds 1104 that are not down-bonds.

FIG. 11B illustrates a large SOI RFIC die with down-bonds as a packaging solution for a stacked FET RF switch in accordance with some embodiments of the disclosed method and apparatus. FIG. 11B illustrates packaged RFIC die 1106 that incorporates a 2 mm×2 mm SOI RFIC die 1108 that allows for down bonds 1110.

FIG. 11C illustrates the effect of a large SOI RFIC die with and without down-bonds on bond inductance in accordance with some embodiments of the disclosed method and apparatus. The large SOI RFIC of FIG. 11A has RF trace inductance well below resonance at 20 GHz, shown by the solid line. In contrast, the large SOI RFIC of FIG. 11B, shown by the dashed line, while below resonance at 20 GHz, has higher RF trace inductance.

FIG. 11D illustrates the effect of a large SOI RFIC die with and without down-bonds on bond resistance in accordance with some embodiments of the disclosed method and apparatus. The bond resistance of the large SOI RFIC dies 1102 is lower, while the bond resistance of the large SOI RFIC dies 1108 is higher. The bonding resistance is limited by the skin effect and is below 350 mOHm at 12 GHz. These experimental results demonstrate that wire bond-based packaging may be an effective solution.

FIG. 11E illustrates the effect of a large SOI RFIC die with down-bonds on bond inductance and resistance as well as the effect on the effective wave impedance in accordance with some embodiments of the disclosed method and apparatus. The effective wave impedance of the large SOI RFIC die 1102 is larger than the effective wave impedance of the large SOI RFIC die 1108.

RF ground inductance differs between SOI RFIC dies 1102 and 1108. The RF ground inductance for SOI RFIC die 1102 is 200 ph, while the RF ground inductance for SOI RFIC die 1108 is 120 ph, for the experimental case described above. The RF ground inductance, therefore, presents another package-induced limit for the die construction. Down-band allow a higher limit, such as 36 dB, according to experimentation.

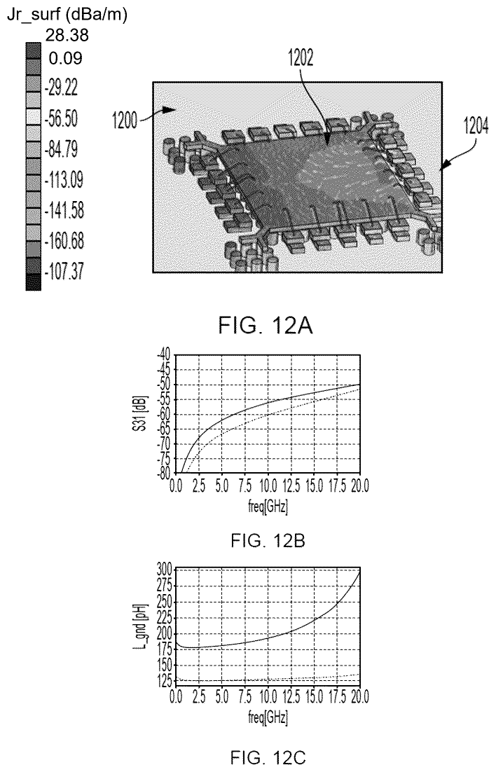

FIG. 12A illustrates an excitation current distribution for a large SOI RFIC die with an RF signal exciting the antenna port, in accordance with some embodiments of the disclosed method and apparatus. The packaged large SOI RFIC die 1200 includes the die 1202 and bonds 1204. The excitation currents were measured for dies with and without down-bonds, where die 1102 is without down-bonds and die 1108 has down-bonds.

FIG. 12B illustrates the coupling-limited boundaries of a large SOI RFIC with and without down-bonds in accordance with some embodiments of the disclosed method and apparatus. As the graph shows, the die without down-bonds has a higher coupling-limited boundary than the die with down bonds. The values used in the model for the die without down-bonds, 1102 has a 200 pH simulated inductance.

FIG. 12C illustrates the packaging ground inductance of a large SOI RFIC die with and without down-bonds in accordance with some embodiments of the disclosed method and apparatus. The die with down-bonds has 128 ph simulated inductance. These values indicated that the practical limit is due to the packaging ground inductance, shown in FIG. 12C. Allowing for down-bonds may allow a higher limit, of approximately 36 dB, whereas not allowing for down-bonds may allow for a limit of 30 dB. Either with or without down-bonds the predicted levels at 12 GHz are within the desired limits.

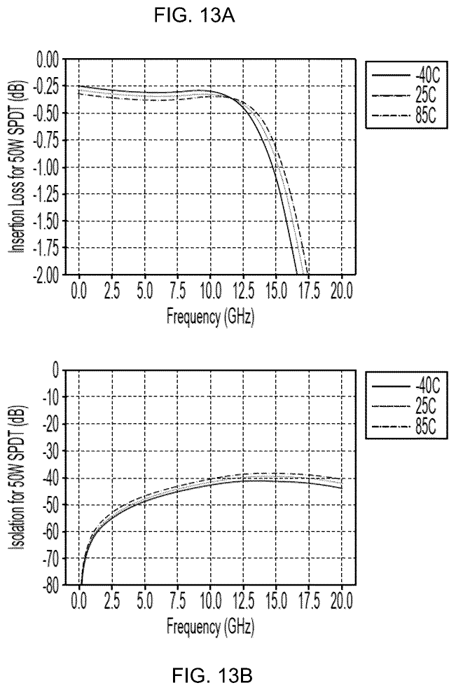

FIGS. 13A and 13B illustrates post layout insertion loss and isolation for a 50 W SPDT switch operating on frequencies up to X-band in accordance with some embodiments of the disclosed method and apparatus. In FIGS. 13A and 13B the device is a 200 nm airgap FET manufacturing using 7SW technology. The FET stack is 20 FETs with a series FET width of 2.5 mm, a shunt FE width of 1.8 mm, a matching inductance of 650 pH (double wire-bond with Z0+80 ohms), and a parasitic ground inductance of 200 pH/shunt FET.

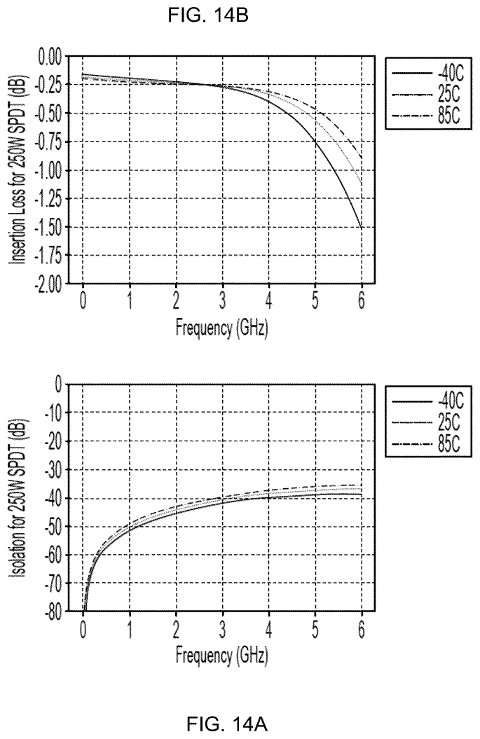

FIGS. 14A and 14B illustrate post layout insertion loss and isolation for a 250 W SPDT switch operating on frequencies in the L and S-bands in accordance with some embodiments of the disclosed method and apparatus. The device in FIG. 14 is a 200 nm airgap FET with 540 FETs manufactured using 7SW technology. The series FET width is 12.5 mm, the shunt FET width is 2.35 mm, the matching inductance is 1200 pH (double wire-bond with Z0=105 ohms0, and a parasitic ground inductance of 200 pH/shunt FET.

### Projected Bandwidth, Insertion Loss, Power Handling, and Isolation

Aspects of the disclosure are directed to a modeling tool that provides rapid prototyping of SPDT switches with desired power handling and bandwidth capabilities. The modeling tool includes the FET parasitics, compensation capacitors for power handling, skin depth, wire-bond inductance, and temperature dependence. An aspect provides a silicon-based SPDT FET switch that is capable of handling 50 W of power at 10 GHz and is also capable of handling 250 W at 3 GHz.

### Thermal Considerations

Thermal dissipation is a major concern for any high-power device, especially the heat generated when the device is operating near the operating limit. In modeling the SPDT FET switches discussed herein, only direct current (DC) losses were considered because reflected power does not cause heating in the switch.

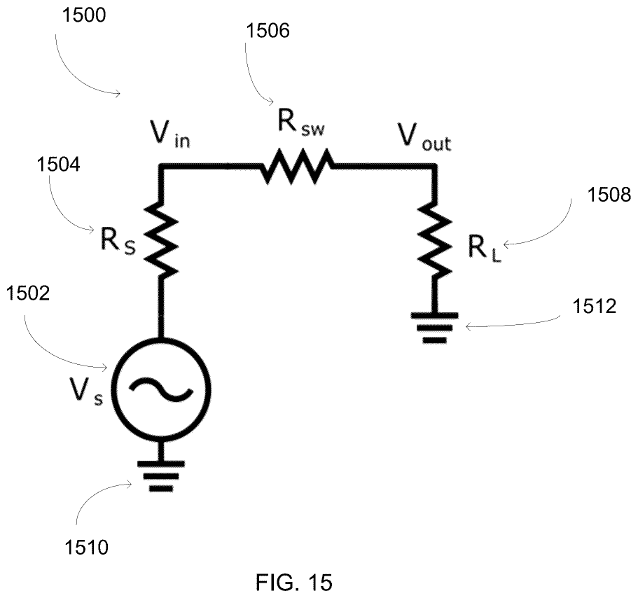

FIG. 15 is a schematic diagram of the DC circuit used for thermal modeling in accordance with some embodiments of the disclosed method and apparatus. The DC circuit 1500 includes a voltage source 1502 that has a resistance Rs, denoted by resistor 1504. The voltage source 1502 is also connected to a ground 1510. The SPDT FET switch receives an input voltage Vin and has an internal resistance R_{switch} denoted by resistor 1506. The SPDT FET switch outputs an output voltage Vₒᵤₜ. Losses in the circuit are considered as resistive losses RL and are denoted by resistor 1508. Resistor RL is connected to ground 1512.

The power dissipated in the SPDT FET switch may be calculated using the equation below:

$${R}_{s w} = {R}_{o} ( 1 + α Δ T ) \qquad EQ . 7$$

Where α is a thermal constant derived from the process design kit, a series of files used in modeling the fabrication process for semiconductors. ΔT is the temperature difference from the base line. The equations for dissipated power for the circuit of FIG. 15 are:

$${V}_{i n} - {V}_{out} = ( \frac{{R}_{s w} + {R}_{L}}{{R}_{s w} + {R}_{L} + {R}_{S}} ) ( 1 - \frac{{R}_{L}}{{R}_{s w} + {R}_{L}} ) {V}_{s} = β {V}_{s} \qquad EQ . 8$$

$${P}_{d i s s} = \frac{{( β {V}_{s} )}^{2}}{{R}_{s w}} , Δ T = {P}_{d i s s} {R}_{th} \qquad EQ . 9$$

The system of EQ. 7 and EQ. 8 may be numerically solved.

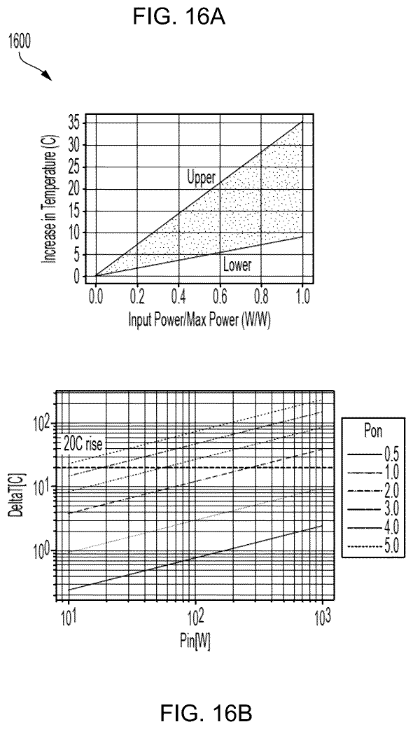

FIGS. 16A and 16B are graphs showing an estimated range of temperature increase based on input power for a 0.3 dB loss SPDT FET switch in accordance with some embodiments of the disclosed method and apparatus. FIG. 16 is the result of numerically solving EQ. 8 and EQ. 9. The estimation used a 400 nm thick buried oxide layer in the SOI substrate. The SOI substrate typically has three layers: a thin silicon layer, where the active devices are located, an insulating layer, which may be known as the buried oxide layer, and a thicker silicon layer, which may be known as the substrate or handle layer. In this estimation the handle layer is 150 um thick with an ideal thermal conductor below the SPDT FET switch chip.

In FIGS. 16A and 16B it is assumed that only the conducting series FET dissipates heat, which produces the upper range of estimated temperature increase. In contrast, the lower estimates assumes that the heat is spread to the other three FETs and is then dissipated throughout the active area of the chip. Because the SPDT FET switches are stacked FET designs the active area increases linearly with increases in power. As a result, the change in temperature depends only on the ratio of input power to maximum power and does not depend on the absolute power passed through the switch. The temperature rise can be kept to a minimum in some process design kits, in some instances the temperature rise can be kept to a minimum for ups for 250 W RF power.

### Fast Switching

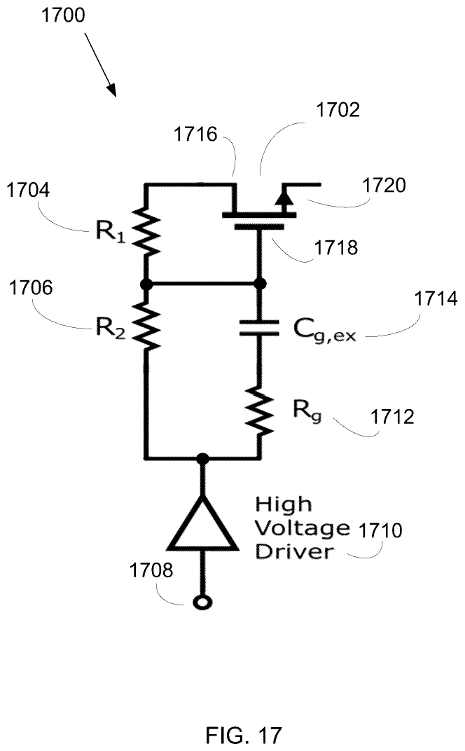

FIG. 17 is a schematic diagram of a fast-switching SOI FET cell in accordance with some embodiments of the disclosed method and apparatus. In typical FET switches a large resistor 1712 is placed between the switch driver 1710 and the gate 1718 of the FET 1702 to isolate the signals and prevent self-activation. This large resistor provides negation of the gate capacitance to ground and may be almost entirely negated for designs intended to operate at high frequencies. A design drawback of this approach is that the switching time is set by the following equation:

$$τ = {R}_{g} {C}_{g} \qquad EQ . 10$$

Where both Rg and Cg are increased linearly with maximum input voltage of the SOI FET switch stack to maintain linearity of power handling and good matching. The switching time increases with maximum voltage Vmax squared, (Vmax)2 and increases linearly with maximum power, Pmax.

At high power, such as 50-100 W, the switching time may be as high as 10 microseconds. Previous designs have attempted to reduce or design-around the switching time by modulating or bypassing the gate resistor to increase the switching speed of the gate resistor, however, those attempts have exposed the gate of the FET to the full RF voltage during the switching interval. This has made it impossible to toggle the switch when high RF power is applied, thus defeating the purpose of trying to speed up the switching speed altogether.

Aspects presented herein in FIG. 17 place an external gate capacitor in 1714 series with the gate resistance to provide the voltage division needed to maintain linearity. The external gate capacitor also provides voltage division of the drive signal, necessitating a high voltage driver for toggling the switch. Secondary parallel resistors provide a path for the DC component of the drive signal to bias the switch indefinitely. This indefinite biasing does not affect the high frequency performance. In cases where bandwidth isn't a limiting factor, such as lower power devices, the gate resistor may be eliminated. Eliminating the gate resistor may lead to the switching time reducing to zero, since the capacitive division is independent of the frequency. In this situation, the switching time may be limited only by the speed of the driver, which may vary from <10 ns up to 100V swings.

The SOI FET switch 1700 includes a FET 1702 that is connected with a resistor R1 1704 as well as a gate capacitor C_{g,ex} 1714. The gate capacitor C_{g,ex} 1714 is connected to a gate resistor R_{g} 1712. Resistor R2 1706 is connected to a high voltage driver 1710. Gate resistor R_{g} 1712 is also connected to the high voltage driver 1710. The high voltage driver 1710 is also connected to an input pin 1708.

The apparatus described above works well for low-power switches and is not suitable for very high-power switches. Eliminating the gate resistance of a high-power switch may lead to excessive capacitance through the gate of the device, thus severely limiting the bandwidth of the device. To maintain the bandwidth and the insertion loss of the SOI FET switch, the value of the gate resistor, R_{g} 1712 must be the same as the value of R_{g} in the conventional FET switch design. When the capacitive gate approach is used in the SOI FET switch design, the speed of the switch is given by the formula below:

$$τ = {R}_{g} {C}_{g} ( \frac{{V}_{gs , max}}{V D D} ) \qquad EQ . 11$$

Where VDD is the gate driver supply voltage and the maximum peak to peak swing of the voltage driver. The total gate capacitance is reduced by the size of the gate capacitance at excitation, C_{gex}. This method provides an improvement for a 50V driver, however, the speed may be increased by approximately ten times over the speed of a conventional switch.

When implementing the design approach illustrated in FIG. 17, the capacitive gate approach, the value of R_{g} 1712 matters when reducing the shunt capacitance to ground and to maintain a wide bandwidth. The gate capacitance, C_{g,ex} 1714 provides the voltage division needed to protect the SOI FET switch from large RF voltages. This holds even when R_{g} 1712 is zero. Because of this, a resistor bypass approach may be effective at reducing switching time when used in conjunction with a capacitive gate design approach. The combination may even be used for hot-switching applications because the high frequency matching of the switch does not matter during the switching interval and C_{g.ex} can adequately protect the SOI FET switch.

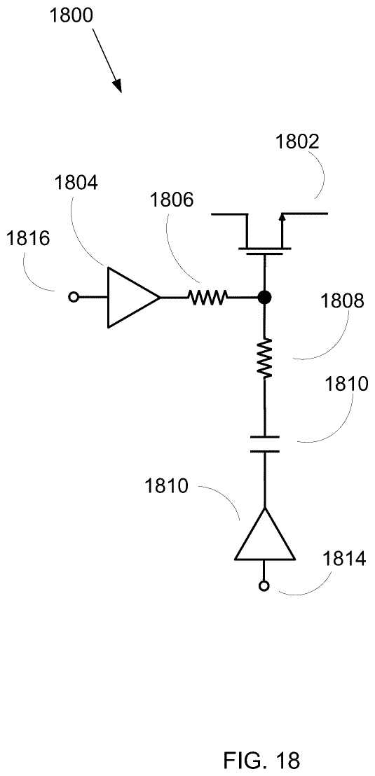

FIG. 18 is a schematic diagram of an embodiment of a fast-switching SOI FET cell in accordance with further embodiments of the disclosed method and apparatus. The SOI FET switch 1800 includes a FET 1802 that is connected with a standard CMOS (Complementary Metal Oxide Silicon) driver 1804 that has an input pin 1816. The CMOS driver 1804 acts as a voltage driver and carries DC bias to the FET 1802. The CMOS driver 1804 provides input to resistor 1806, which in turn connects to the FET 1802. The FET 1802 is also connected to a gate resistor R_{g}, 1808 which is in turn connected to a gate capacitor C_{g, ex} 1810. The gate capacitor C_{g, ex} 1810 is also connected to a high voltage driver 1810. The high voltage driver 1810 is also connected to an input pin 1814. The input pin 1814, CMOS driver 1804 and resistor 1806 replace the voltage divider of SOI FET resistors R₁ 1704 and R₂ 1706 are connected to the input of the FET 1802.

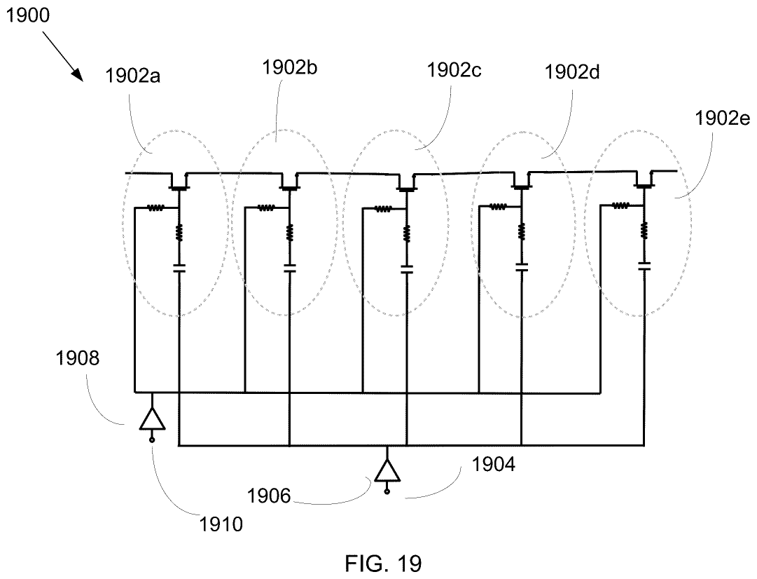

FIG. 19 is a schematic diagram of a stacked fast-switching SOI FET assembly in accordance with further embodiments of the disclosed method and apparatus. The fast-switching SOI FET assembly 1900 comprises multiple FETs 1902a, b, c, d, and e. The source of FET 1902a is connected to the drain of FET 1902b, while the source of FET 1902b is connected to the drain of 1902c, and the source of FET 1902c is connected to the drain of 1902d. Similarly, the source of FET 1902d is connected to the drain of FET 1902e. A high voltage driver 1906 is connected to the FETs 1902a-e gates. the high voltage driver 1906 receives signal input from input pin 1904. A CMOS driver 1908 provides biasing FETS 1902a-e gates and has an input pin 1910.

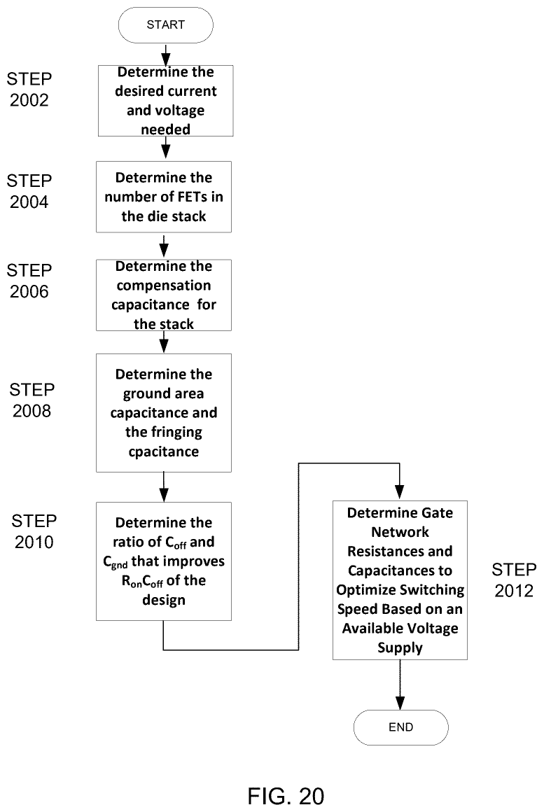

FIG. 20 is a flowchart illustrating the method by which a semiconductor switch assembly driver stack is designed and manufactured in accordance with some disclosed embodiments. The method 2000 starts with determining the desired current and voltage needed to perform the drive function for the which the driver is being designed (STEP 2002).

Next, the number of FETs to be used in the stacked driver circuit is determined (STEP 2004). This determination is based on the desired amount of current and the voltage at the driver output. In order to more clearly explain the method, the stacked driver circuit 1900 of FIG. 19 will be used as an example of a stacked driver circuit to be designed and manufactured. It will be clear that any particular integer number of FETs can be used in a stacked driver circuit to be designed using this method but typically will be on the order of 22 FETs.

Once the total number of FETs to be used in the stack is determined, an amount of compensation capacitance for the stack is determined (STEP 2006). Next, the ground area capacitance and the fringing capacitance are determined (STEP 2008). The ratio C_{off} and C_{ground} that improve the ratio RₒₙC_{off} of the design are determined (STEP 2010). Then the gate network resistances and capacitances are determined to optimize switching speed based on an available voltage supply. (STEP 2012) Finally, the ratio is optimized to improve device power handling and thermal efficiency (STEP 2014).

Aspects of the embodiments discussed above provide for a switch comprising a control signal port connected to a high voltage driver, a signal input port and an output port. A FET having a gate, drain, and source is also part of the switch. The source of the FET is connected to the signal output port and the drain is connected to the signal input port as well as to a first resistor that provides a signal path between the drain and the gate of the FET. A first capacitor is connected in series with the gate of the FET, a second resistor is connected in series between the gate of the FET and the first capacitor. A third resistor is connected in parallel with the first capacitor and the second resistor.

A further embodiment provides a switch assembly that also includes a control signal port connected to a high voltage driver, a signal input port, and a signal output port. A FET having a gate, drain and source is also included in the switch assembly. The source of the FET is connected to the signal output port and the drain of the FET is connected to the input port. A first resistor is connected to the gate of the FET and also to a low voltage driver. A second resistor is coupled between the gate of the FET and also to a first capacitor. A high voltage driver is connected to the first capacitor and the control signal port. At least two FETs may be stacked and the number of stacked FETs may be unlimited.

A still further embodiment provides a method of manufacturing a switch assembly of the embodiments described herein. The method contains the following steps: determine an amount of current and an amount of voltage needed for switch operation; determine a number of FETs to be stacked to form the switch assembly; determine a compensation capacitance for the number of FETs to be stacked to form the switch assembly; determine a ground area capacitance and a fringing capacitance for the number of FETs to be stacked to form the switch assembly; determine a ratio of off capacitance and ground capacitance that improves a ratio of on resistance on off capacitance for the number of FETs to be stacked to form the switch assembly; optimize the ratio of on resistance and off capacitance based on power handling and thermal efficiency; determine the gate network resistances an capacitances to optimize switching speed based on an available voltage supply; and fabricate the switch assembly based on the optimized ratio.

What is claimed is:

1. A switch comprising:
a) a control signal port connected to a high voltage driver;
b) a signal input port and an output port;
c) a field effect transistor (FET) having a gate, drain and source, the source connected to the signal output port and the drain connected to the signal input port and to a first resistor that provides a signal path between the drain and the gate of the FET;
d) a first capacitor that is connected in series with the gate of the FET;
e) a second resistor connected in series between the gate of the FET and the first capacitor; and
f) a third resistor connected in parallel with the first capacitor and the second resistor.

2. The switch of claim 1, wherein the FET is a negative field effect transistor (NFET).

3. The switch of claim 1, wherein the switch is packaged as a silicon-on-insulator (SOI) radio frequency integrated circuit (RFIC) die.

4. The switch of claim 3, wherein the SOI RFIC die does not incorporate down-bonds.

5. The switch of claim 3, wherein the SOI RFIC die incorporates down-bonds.

6. The switch of claim 3, wherein the switch is manufactured using a first proprietary mask, denoted 7SW.

7. The switch of claim 3, wherein the switch is manufactured using a second proprietary mask, denoted 9SW.

8. The switch of claim 7, wherein the 9SW mask is a higher performance mask than the 7SW mask.

9. The switch of claim 6, wherein the FET measures 200 nm and the FETs may be stacked on top of one another.

10. The switch of claim 1, wherein the first and second resistors comprise a voltage divider.

11. A switch comprising:
a) a control signal port connected to a high voltage driver;
b) a signal input port and a signal output port;
c) a field effect transistor (FET) having a gate, drain and source, the source connected to the signal output port and the drain connected to the input port;
d) a first resistor connected to the gate of the FET and to a low voltage driver
e) a second resistor coupled between the gate of the FET and to a first capacitor; and
f) a high voltage driver connected to the first capacitor and the control signal port.

12. The switch of either claim 1, wherein the at least two FETs are connected in series with one another, with the possible number of series FETs being unlimited, and the gate networks are connected in parallel.

13. The switch of claim 11, wherein the at least two FETs are connected in series with one another, with the possible number of series FETs being unlimited, and the gate networks are connected in parallel.

14. The switch of claim 1, wherein the first and second resistors form a DC voltage divider.

15. A method of manufacturing a switch assembly, comprising:
determine an amount of current and an amount of voltage needed for switch operation;
determine a number of field effect transistors (FETs) to be stacked to form the switch assembly;
determine a compensation capacitance for the number of FETs to be stacked to form the switch assembly;
determine a ground area capacitance and a fringing capacitance for the number of FETs to be stacked to form the switch assembly;
determine a ratio of off capacitance and ground capacitance that improves a ratio of on resistance and off capacitance for the number of FETs to be stacked to form the switch assembly;
optimize the ratio of on resistance and off capacitance based on power handling and thermal efficiency;
determine gate network resistances and capacitances to optimize switching speed based on an available voltage supply; and
fabricate the switch assembly based on the optimized parameters.

16. The method of claim 15, wherein the number of FETs to be stacked is at least two FETs.

17. The method of claim 15, wherein the number of FETs to be stacked is unlimited.

18. The method of claim 15, wherein the switch assembly is fabricated using down-bonds.

19. The method of claim 15, wherein the switch assembly fabrication does not incorporate down bonds.

20. The method of claim 15, wherein the switch assembly fabrication uses a high performance mask.
